(19) United States
(12) Patent Application Publication
(10) Pub. No.: US 2019/0011747 A1
(43) Pub. Date: Jan. 10, 2019

(54) LIQUID CRYSTAL DISPLAY PANEL AND METHOD FOR CORRECTING SAME

(71) Applicant: SHARP KABUSHIKI KAISHA, Sakai City, Osaka (JP)

(72) Inventors: FUMIKAZU SHIMOSHIKIRYOH, Sakai City (JP); TAKEHISA YOSHIDA, Sakai City (JP)

(73) Assignee: SHARP KABUSHIKI KAISHA, Sakai City, Osaka (JP)

(21) Appl. No.: 15/752,434

(22) PCT Filed: Aug. 12, 2016
(86) PCT No.: PCT/JP2016/073750

§ 371 Date: Feb. 13, 2018

(30) Foreign Application Priority Data
Aug. 21, 2015 (JP) 2015-163658

(51) Int. Cl. G02F 1/133; H01L 27/12; G02F 1/1362; G02F 1/1343

(52) U.S. Cl. CPC G02F 1/13306; H01L 27/1214; G02F 2001/134354; G02F 1/1343; G02F 1/136286

(57) ABSTRACT

A display region (10d) of a liquid crystal display panel (100) has a first display region (10da) and a second display region (10db). In the display region (10d), a gate bus line (12) extends in a first direction and a source bus line (14) extends in a second direction. A first gate driver (32) and a first source driver (35) for driving a first pixel in the first display region and a second gate driver (32) and a second source driver (35) for driving a second pixel in the second display region are respectively provided. The liquid crystal display panel (100) is further provided with a plurality of first auxiliary wirings (15) extending in the second direction and provided between two first pixels adjacent to each other in the first direction, and a plurality of second auxiliary wirings (15) extending in the second direction and provided between two second pixels adjacent to each other in the first direction.

### TECHNICAL FIELD

The present invention relates to a liquid crystal display panel and a method for correcting the same, and in particular, to a large-sized liquid crystal display panel for high-definition television applications and a method for correcting disconnection of a source bus line. Here, the liquid crystal display panel refers to a TFT type liquid crystal display panel, unless otherwise specified.

### BACKGROUND ART

In order to improve the manufacturing yield of liquid crystal display panels, methods for correcting source bus line disconnection are being studied. For example, PTL 1 discloses a liquid crystal display panel 900 schematically shown in FIG. 14. The liquid crystal display panel 900 includes a TFT substrate 10X, a counter substrate 20X, and a liquid crystal layer (not shown) provided therebetween. In a region of the TFT substrate 10X corresponding to the display region 10d of the liquid crystal display panel 900, there are formed pixel electrodes (not shown) arranged in a matrix, TFTs (not shown) having a drain electrode (not shown) connected to each pixel electrode, a gate bus line 12 connected to the gate electrode (not shown) of the TFT, and a source bus line 14 connected to the source electrode (not shown) of the TFT. A gate signal voltage (also referred to as a scanning signal voltage) is supplied from a gate drive circuit (referred to below as a “gate driver”) 32 to the gate bus line 12 and a source signal voltage (also referred to as a display signal voltage or a grayscale voltage) is supplied from a source drive circuit (referred to below as a “source driver”) 35 to the source bus line 14.

In the liquid crystal display panel 900, the output from the source driver 35 is supplied to the source bus line 14 in which a disconnection 14f has occurred from the end of the source bus line 14 separated from the source driver 35 via auxiliary wiring 95 provided outside the display region 10d. That is, the source signal voltage from the source driver 35 is directly supplied to one end of the source bus line 14 in which the disconnection 14f has occurred, and the source signal voltage from the source driver 35 is supplied to the other end via the auxiliary wiring 95. Here, the source bus line 14 in which the disconnection 14f has occurred and the auxiliary wiring 95 are connected to each other using a known laser repair device. That is, a portion where the source bus line 14 and the auxiliary wiring 95 overlap each other is irradiated with laser light and the wiring material is melted to form a connection point 95m. In this manner, it is possible to supply the source signal voltage from both the upper and lower sides to the source bus line 14 in which the disconnection 14f has occurred.

However, since the auxiliary wiring 95 is provided at the periphery of the display region 10d, a path for supply via the auxiliary wiring 95 becomes longer. In order to compensate for the voltage drop due to this auxiliary wiring 95, the output from the source driver 35 is output to the source bus line 14 via a buffer circuit 34. In the drawings below, common reference numerals are attached to constituent elements which are generally included in a liquid crystal display panel and which have substantially the same functions, and descriptions thereof may be omitted.

### CITATION LIST

### Patent Literature

PTL 1: Japanese Unexamined Patent Application Publication No. 6-315337

### SUMMARY OF INVENTION

### Technical Problem

The correction method described in PTL 1 is effective in a case where the source driver 35 is arranged along one side (the upper side, for example) of the liquid crystal display panel 900 as schematically shown in FIG. 14.

However, a large-sized high-definition liquid crystal display panel exceeding an FHD of 4K or 8K may adopt a configuration, for example, in which the display region of the liquid crystal display panel is divided vertically, a source driver supplies a source signal voltage to the source bus line of the upper display region is provided on an upper side, and a source driver which supplies a source signal voltage to a source bus line of the lower display region is provided on the lower side (referred to below as “vertically divided driving structure”). As described above, it is not possible to apply the correction method described in PTL 1 to a liquid crystal display panel in which source drivers are arranged on two opposing sides (for example, upper side and lower side) of a liquid crystal display panel.

The present invention was made to solve the above problem and has an object of providing a liquid crystal display panel provided with a structure capable of repairing disconnection of a source bus line, for example, having a vertically divided driving structure, and a method for repairing the same.

### Solution to Problem

A liquid crystal display panel according to an embodiment of the present invention includes a first display region having a plurality of first pixels arranged in a first direction and a second direction different from the first direction, a second display region having a plurality of second pixels arranged in the first direction and the second direction and provided at a position different from the first display region, a plurality of first transistors provided in the first display region and each connected to any one of the plurality of first pixels, a plurality of second transistors provided in the second display region and each connected to any one of the plurality of second pixels, a plurality of first gate bus lines each extending in the first direction and connected to any one of the plurality of first transistors, a plurality of second gate bus lines each extending in the first direction and connected to any one of the plurality of second transistors, a plurality of first source bus lines each extending in the second direction and connected to any one of the plurality of first transistors, a plurality of second source bus lines each extending in the second direction and connected to any one of the plurality of second transistors, a plurality of first auxiliary wirings each extending in the second direction and provided between two first pixels adjacent to each other in the first direction in the plurality of first pixels, a plurality of second auxiliary wirings each extending in the second direction and provided between two second pixels adjacent to each other in the first direction in the plurality of second pixels, a first source driver provided around the first display region and supplying a display signal voltage to the plurality of first source bus lines, and a second source driver provided around the second display region and supplying a display signal voltage to the plurality of second source bus lines.

In one embodiment, the plurality of first auxiliary wirings and the plurality of second auxiliary wirings are arranged at a frequency with a ratio of one or less with respect to three first pixels and three second pixels arranged in the first direction, respectively.

In one embodiment, the liquid crystal display panel further includes a first buffer circuit provided between the first source driver and the plurality of first auxiliary wirings, and a second buffer circuit provided between the second source driver and the plurality of second auxiliary wirings.

In one embodiment, the liquid crystal display panel further includes a conductive ring provided to surround the first display region and the second display region, in which the plurality of first auxiliary wirings and the plurality of second auxiliary wirings are connected to the conductive ring.

In one embodiment, the liquid crystal display panel further includes a plurality of first connection wirings extending in the first direction and each associated with one pixel row formed of a plurality of first pixels arranged in the first direction in the plurality of first pixels, and a plurality of second connection wirings extending in the first direction and each associated with one pixel row formed of a plurality of second pixels arranged in the first direction in the plurality of second pixels.

In one embodiment, the liquid crystal display panel, in which each of the plurality of first pixels and the plurality of second pixels has an auxiliary capacitance, further includes a plurality of auxiliary capacitance wirings extending in the first direction and each connected to the auxiliary capacitances belonging to one pixel row formed of a plurality of first pixels or a plurality of second pixels arranged in the first direction in the plurality of first pixels or the plurality of second pixels, in which at least part of the plurality of auxiliary capacitance wirings have a branched structure.

In one embodiment, the liquid crystal display panel further includes a plurality of pixel electrodes corresponding to each of the plurality of first pixels and the plurality of second pixels, in which at least part of the plurality of pixel electrodes have a notched portion on a side close to at least one associated source bus line in the plurality of first source bus lines and the plurality of second source bus lines.

In one embodiment, the liquid crystal display panel, in which each of the plurality of first pixels and the plurality of second pixels has a first subpixel and a second subpixel arranged in the second direction, the first subpixel has a first auxiliary capacitance, and the second subpixel has a second auxiliary capacitance, further includes a plurality of first auxiliary capacitance wirings extending in the first direction and each connected to the first auxiliary capacitances belonging to one pixel row formed of a plurality of first pixels or a plurality of second pixels arranged in the first direction in the plurality of first pixels or the plurality of second pixels, a plurality of second auxiliary capacitance wirings extending in the first direction and each connected to the second auxiliary capacitances belonging to one pixel row formed of a plurality of first pixels or a plurality of second pixels arranged in the first direction in the plurality of first pixels or the plurality of second pixels, and a plurality of third auxiliary capacitance wirings each provided in parallel with a first auxiliary capacitance wiring and a second auxiliary capacitance wiring associated with pixel rows adjacent to each other, and electrically connected to the first auxiliary capacitance wiring and the second auxiliary capacitance wiring.

In one embodiment, in the liquid crystal display panel, two pixels arranged in the second direction are set as a k-th row pixel and a k+1-th row pixel and a second subpixel in each of the two pixels is arranged next to a first subpixel in the second direction, and the liquid crystal display panel further includes an auxiliary capacitance coupling wiring electrically connecting a second auxiliary capacitance wiring associated with the second subpixel of the k-th row pixel, a first auxiliary capacitance wiring associated with the first subpixel of the k+1-th row pixel, and a corresponding third auxiliary capacitance wiring provided between the second auxiliary capacitance wiring and the first auxiliary capacitance wiring in the plurality of third auxiliary capacitance wirings.

In one embodiment, the auxiliary capacitance coupling wiring is formed only in preselected pixels, and a ratio of the pixels in which the auxiliary capacitance coupling wiring is formed is one ninth or less.

In one embodiment, the liquid crystal display panel, in which each of the plurality of first pixels and the plurality of second pixels has a first subpixel and a second subpixel arranged in the second direction, the first subpixel has a first auxiliary capacitance, and the second subpixel has a second auxiliary capacitance, further includes a plurality of first auxiliary capacitance wirings extending in the first direction and each connected to the first auxiliary capacitances belonging to one pixel row formed of a plurality of first pixels or a plurality of second pixels arranged in the first direction in the plurality of first pixels or the plurality of second pixels, a plurality of second auxiliary capacitance wirings extending in the first direction and each connected to the second auxiliary capacitances belonging to one pixel row formed of a plurality of first pixels or a plurality of second pixels arranged in the first direction in the plurality of first pixels or the plurality of second pixels, a plurality of first connection wirings extending in the first direction and each associated with one pixel row formed of a plurality of first pixels arranged in the first direction in the plurality of first pixels, and a plurality of second connection wirings extending in the first direction and each associated with one pixel row formed of a plurality of second pixels arranged in the first direction in the plurality of second pixels.

In one embodiment, the liquid crystal display panel further includes a plurality of first subpixel electrodes corresponding to each of the plurality of first subpixels, and a plurality of second subpixel electrodes corresponding to each of the plurality of second subpixels, in which part of each of the plurality of first subpixel electrodes and the plurality of second subpixel electrodes have a notched portion on a side close to at least one associated source bus line in the plurality of first source bus lines and the plurality of second source bus lines.

In one embodiment, the notched portions are alternately formed in the second direction on a right side and a left side of the plurality of first subpixel electrodes and the plurality of second subpixel electrodes.

A correction method for a liquid crystal display panel according to an embodiment of the present invention is a correction method for any one of the liquid crystal display panels. The method includes any one of a step in which, when a disconnection occurs in one of the plurality of first source bus lines, the first source bus line where the disconnection has occurred and one of the plurality of first auxiliary wirings are connected, or a step in which, when a disconnection occurs in one of the plurality of second source bus lines, the second source bus line where the disconnection has occurred and one of the plurality of second auxiliary wirings are connected.

In one embodiment, the liquid crystal display panel has a plurality of wirings provided in the first display region and the second display region and each extending in the first direction and electrically independent from the plurality of the first gate bus lines and the plurality of second gate bus lines, and the method further includes a step of connecting via one of the plurality of wirings between the first source bus line where the disconnection has occurred and the one of the first auxiliary wirings or between the second source bus line where the disconnection has occurred and the one of the second auxiliary wirings.

### Advantageous Effects of Invention

According to an embodiment of the present invention, there is provided a liquid crystal display panel having a vertically divided driving structure provided with a structure capable of repairing disconnection of a source bus line, and a method for repairing the same.

### BRIEF DESCRIPTION OF DRAWINGS

FIG. 1 is a schematic plan view of a liquid crystal display panel 100 according to Embodiment 1 of the present invention.

FIG. 2(a) is a schematic plan view of a liquid crystal display panel 200 according to Embodiment 2 of the present invention, FIG. 2(b) is a schematic plan view of a diode ring 44 of the liquid crystal display panel 200, and FIG. 2(c) is a schematic plan view of another diode ring 44T.

FIG. 3 is a plan view schematically showing a structure of a TFT substrate 10A used in a liquid crystal display panel according to Embodiment 3 of the present invention.

FIG. 4 is a plan view schematically showing a structure of a TFT substrate 10B used in a liquid crystal display panel according to Embodiment 4 of the present invention.

FIG. 5 is a plan view schematically showing a structure of a TFT substrate 10C used in a liquid crystal display panel according to Embodiment 5 of the present invention.

FIG. 6 is a plan view schematically showing a structure of a TFT substrate 10D used in a liquid crystal display panel according to Embodiment 6 of the present invention.

FIG. 7 is a plan view schematically showing a structure of a TFT substrate 10E used in a liquid crystal display panel according to Embodiment 7 of the present invention.

FIG. 8 is a plan view schematically showing a structure of a TFT substrate 10F used in a liquid crystal display panel according to Embodiment 8 of the present invention.

FIG. 9 is a plan view schematically showing a structure of a TFT substrate 10G used in a liquid crystal display panel according to Embodiment 9 of the present invention.

FIG. 10 is a plan view schematically showing a structure of a TFT substrate 10H used in a liquid crystal display panel according to Embodiment 10 of the present invention.

FIG. 11 is a plan view schematically showing a structure of a TFT substrate 10I used in a liquid crystal display panel according to Embodiment 11 of the present invention.

FIG. 12 is a plan view schematically showing an example of a structure of a portion for cutting of an auxiliary capacitance wiring of a liquid crystal display panel according to an embodiment of the present invention.

FIG. 13 is a plan view schematically showing another example of a structure of a portion for cutting of an auxiliary capacitance wiring of a liquid crystal display panel according to an embodiment of the present invention.

FIG. 14 is a schematic plan view of a liquid crystal display panel 900 of the related art.

### DESCRIPTION OF EMBODIMENTS

A description will be given below of a liquid crystal display panel according to an embodiment of the present invention and a method for correcting the same with reference to the drawings.

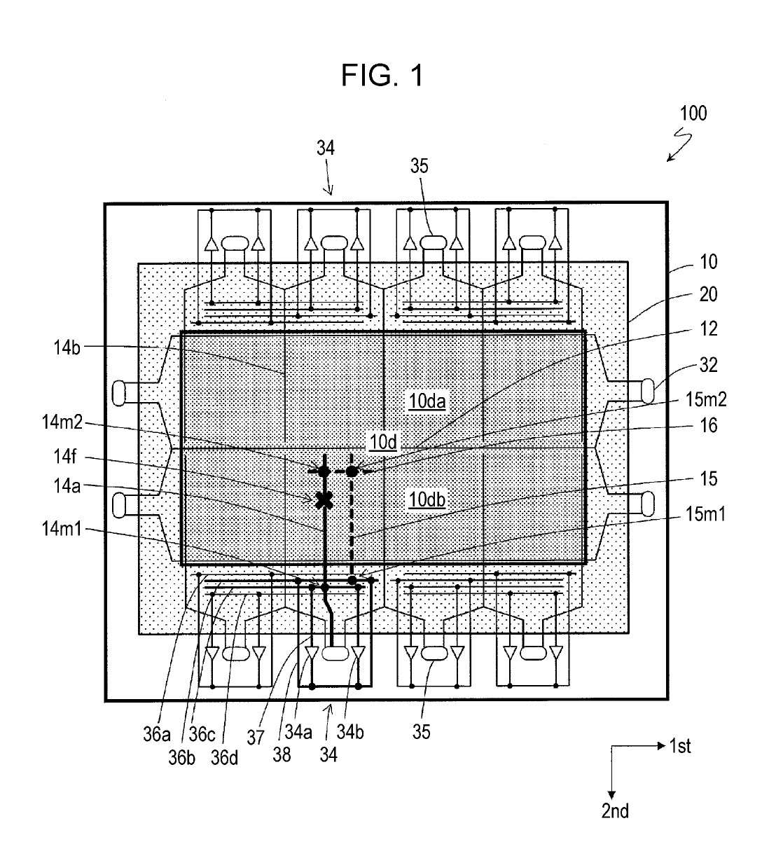

FIG. 1 is a schematic plan view of a liquid crystal display panel 100 according to Embodiment 1 of the present invention.

The liquid crystal display panel 100 has a TFT substrate 10, a counter substrate 20, and a liquid crystal layer (not shown) provided therebetween. In a region of the TFT substrate 10 corresponding to the display region 10d of the liquid crystal display panel 100, pixel electrodes (not shown) arranged in a matrix, TFTs (not shown) in which a drain electrode (not shown) is connected to each pixel electrode, a gate bus line 12 connected to a gate electrode (not shown) of the TFT, and source bus lines 14a and 14b connected to a source electrode (not shown) of the TFT, are formed. A gate signal voltage is supplied from the gate driver 32 to the gate bus line 12, and a source signal voltage is supplied from the source driver 35 to the source bus lines 14a and 14b.

Here, the liquid crystal display panel 100 exemplified here has a double source structure and has one of the source bus lines 14a and 14b on each side of a plurality of pixels arranged in the second direction and, in the diagrams, the source bus line provided on the left side of the pixel is denoted as the source bus line 14a and the source bus line provided on the right side of the pixel is denoted as the source bus line 14b. As will be described below, the liquid crystal display panel according to the embodiment of the present invention may not have a double source structure.

The liquid crystal display panel 100 has a vertically divided driving structure. That is, the liquid crystal display panel 100 includes a first display region 10da having a plurality of first pixels arranged in a first direction and a second direction different from the first direction, and a second display region 10db having a plurality of second pixels arranged in the first direction and the second direction and provided at a position different from the first display region 10da. Below, the first display region 10da may be referred to as an upper display region 10da and the second display region 10db may be referred to as a lower display region 10db. Since the structure of the liquid crystal display panel 100 has a substantially vertically symmetrical structure, a description will be given mainly of the structure on the lower side. The first display region 10da and the second display region 10db are not necessarily arranged vertically, and may be arranged horizontally depending on the shape of the liquid crystal display panel. An example in which the first display region 10da is arranged on the upper side and the second display region 10db is arranged on the lower side will be described below. In the illustrated liquid crystal display panel, the first direction is the horizontal direction, the second direction is the vertical direction, a plurality of pixels arranged in the first direction are referred to as a pixel row, and a plurality of pixels arranged in the second direction are referred to as a pixel column. Note that the first direction and the second direction are not limited to this example.

A plurality of first transistors (not shown) are provided in the first display region 10da of the TFT substrate 10, and each is connected to any one of the plurality of first pixels. A plurality of second transistors are provided in the second display region 10db, and each is connected to any one of the plurality of second pixels. Note that two or more transistors may be provided in each of the first pixel and the second pixel.

The TFT substrate 10 has a plurality of gate bus lines 12 extending in the first direction. In the first display region 10da, each of the plurality of first gate bus lines 12 is connected to any one of a plurality of first transistors, and in the second display region 10db, each of a plurality of second gate bus lines 12 is connected to any one of the plurality of second transistors.

In addition, the TFT substrate 10 has a plurality of source bus lines 14a and 14b extending in the second direction. In the first display region 10da, each of the plurality of first source bus lines 14a and 14b is connected to any one of a plurality of first transistors, and in the second display region 10db, each of the plurality of second source bus lines 14a and 14b is connected to any one of a plurality of second transistors.

The TFT substrate 10 further has a plurality of first auxiliary wirings 15 and a plurality of second auxiliary wirings 15 extending in the second direction. Each of the plurality of first auxiliary wirings 15 is provided between two first pixels (two first pixel columns) adjacent to each other in the first direction in the plurality of first pixels in the first display region 10da. Each of the plurality of second auxiliary wirings 15 is provided between two second pixels (two second pixel columns) adjacent to each other in the first direction in the plurality of second pixels in the second display region 10db. As exemplified later, the plurality of first auxiliary wirings 15 and the plurality of second auxiliary wirings 15 are arranged at a frequency with a ratio of one or less, for example, in each of the three pixel columns.

The liquid crystal display panel 100 is provided with a first source driver 35 (arranged on the upper side of the display region 10d in FIG. 1) provided around the first display region 10da for supplying a display signal voltage to the plurality of first source bus lines 14a and 14b, and a second source driver 35 (arranged on the lower side of the display region 10d in FIG. 1) provided around the second display region 10db for supplying a display signal voltage to the plurality of second source bus lines 14a and 14b.

A first buffer circuit 34 is provided between the first source driver 35 arranged on the upper side of the first display region 10da and the plurality of first auxiliary wirings 15, and a second buffer circuit 34 is provided between the second source driver 35 arranged on the lower side of the second display region 10db and the plurality of second auxiliary wirings 15.

For example, the second buffer circuit 34 has two buffers (buffer amplifiers) 34a and 34b, and amplifies the current of the output (source signal voltage) from the second source driver 35. The source signal voltage current-amplified by the second buffer circuit 34 is supplied to the source bus line 14a in which the disconnection 14f has occurred via the second auxiliary wiring 15.

The connection between the output of the source driver 35 to the source bus line 14a in which the disconnection 14f has occurred and the input of the buffers 34a and 34b, the connection between the outputs of the buffers 34a and 34b and the second auxiliary wiring 15, and the connection between the second auxiliary wiring 15 and the source bus line 14a in which the disconnection 14f has occurred are performed, for example, as follows.

The buffer circuit 34 has, for example, buffer connection wirings 36a, 36b, 36c, and 36d, an input wiring 37, and an output wiring 38. The buffer connection wirings 36a, 36b, 36c, and 36d, the input wiring 37, the output wiring 38, the source bus line 14a, and the second auxiliary wiring 15 are insulated from each other. When correcting the source bus line 14a in which the disconnection 14f has occurred, connecting necessary portions to each other using a known laser repair device makes it possible to supply a predetermined source signal voltage to the source bus line 14a in which the disconnection 14f has occurred via the second auxiliary wiring 15.

For example, as shown in FIG. 1, the source bus line 14a, in which the disconnection 14f has occurred, of the source driver 35 and the buffer connecting wiring 36c are connected to each other at a connection point 14m1 formed by melting the intersecting portions thereof. The input wiring 37 of each of the buffers 34a and 34b is connected to the buffer connecting wiring 36c, and the output wiring 38 of each of the buffers 34a and 34b is connected to the buffer connecting wiring 36b. The second auxiliary wiring 15 and the buffer connecting wiring 36b are connected to each other via a connection point 15m1 formed by melting the intersecting portions thereof.

The second auxiliary wiring 15 and a wiring (for example, a wiring formed from the same metal layer as the auxiliary capacitance wiring) 16 extending in the first direction are connected to each other via a connection point 15m2 formed by melting the intersecting portions thereof.

The wiring 16 extending in the first direction and the source bus line 14a in which the disconnection 14f has occurred are connected to each other at a connection point 14m2 formed by melting the intersecting portions thereof.

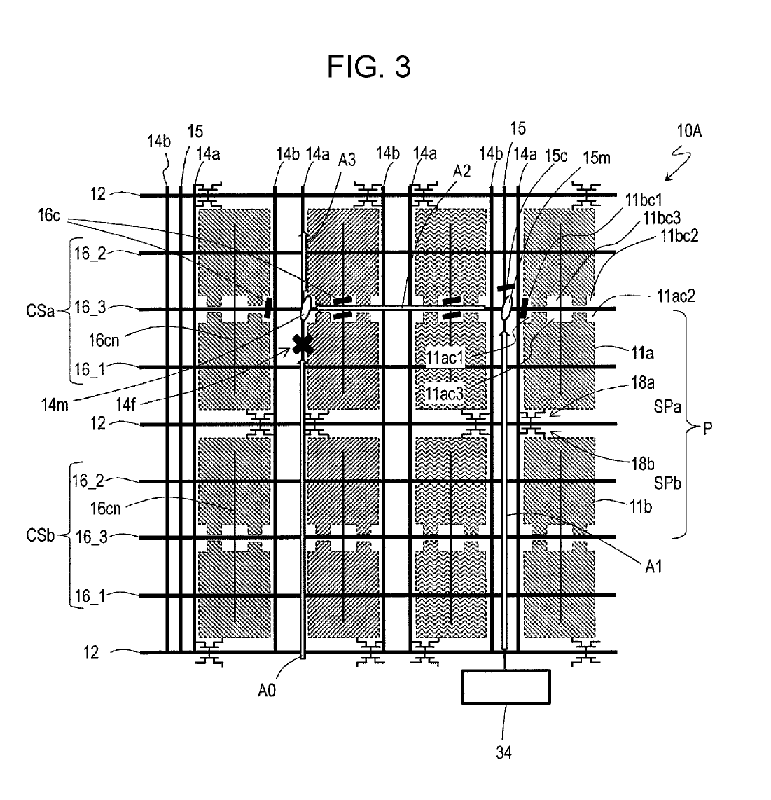

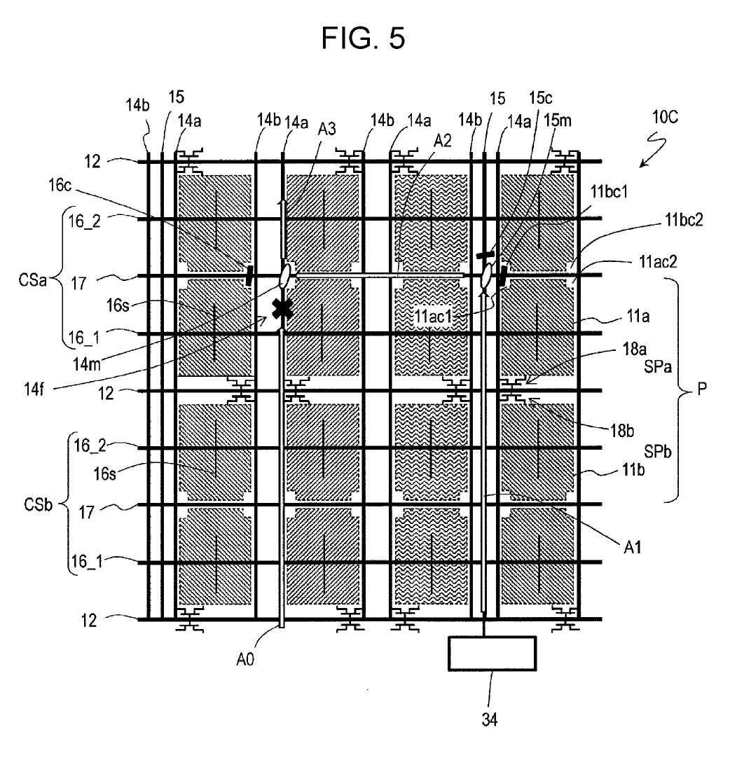

As the wiring 16 extending in the first direction, for example, it is also possible to use a part of the auxiliary capacitance wiring having a branched structure (for example, refer to the third auxiliary capacitance wiring 16_3 in FIG. 3), or it is possible to use a connection wiring provided for correction (for example, refer to the connection wiring 17 in FIG. 5).

In this manner, the output of the source driver 35 to the source bus line 14a in which the disconnection 14f has occurred is supplied to the source bus line 14a via the second auxiliary wiring 15. Since it is possible to shorten the first and second auxiliary wirings 15 of the liquid crystal display panel 100 in comparison with the auxiliary wiring 95 of the liquid crystal display panel 900 of the related art shown in FIG. 14, it is also possible to omit the buffer circuit 34.

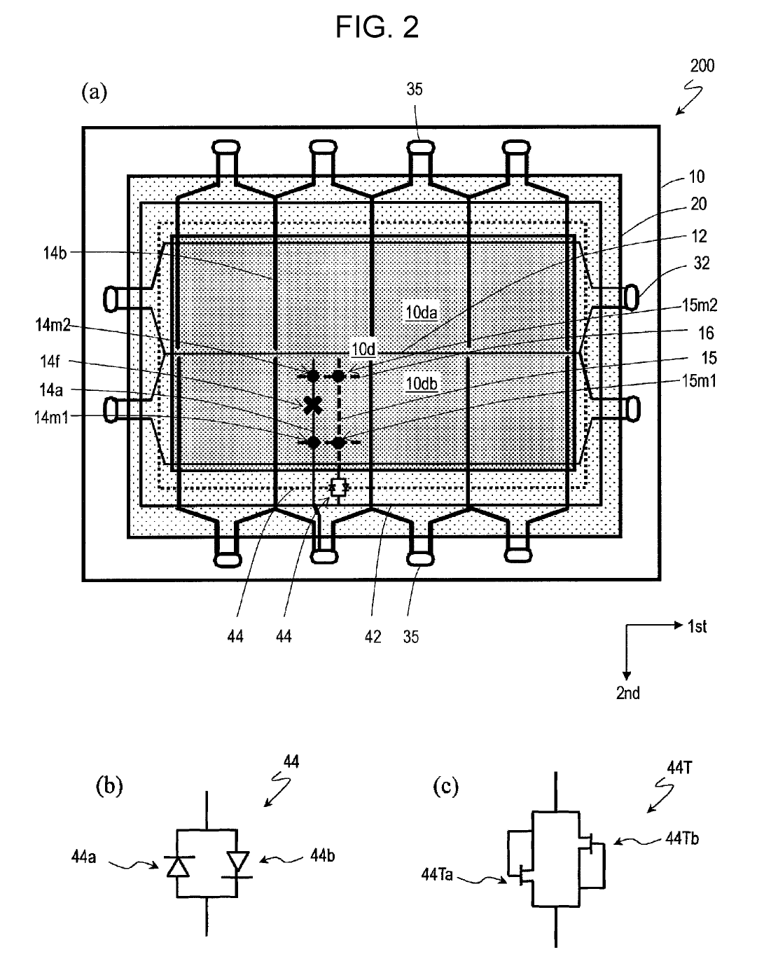

FIG. 2(a) is a schematic plan view of the liquid crystal display panel 200 according to Embodiment 2 of the present invention. The liquid crystal display panel 200 does not have the buffer circuit 34 of the liquid crystal display panel 100.

The liquid crystal display panel 200 has a conductive ring 42 provided so as to surround the display region 10d, and the plurality of first auxiliary wirings 15 and the plurality of second auxiliary wirings 15 are connected to the conductive ring 42. In this manner, connecting the first auxiliary wiring 15 and the second auxiliary wiring 15 to the conductive ring 42 makes it possible to inhibit the first auxiliary wiring 15 and the second auxiliary wiring 15 which are not used for correction from entering an electrically floating state. When there is a wiring in an electrically floating state, static electricity is accumulated therein, which may cause a static electricity breakdown.

The first and second auxiliary wirings 15 (only the second auxiliary wiring 15 on the lower side is shown for simplicity in FIG. 2(a)) are connected to the conductive ring 42 via a diode ring 44. As shown in FIG. 2(b), the diode ring 44 has two diodes 44a and 44b and is configured so as to diffuse an electrical charge in both directions. In FIG. 2(a), only one diode is shown, but as indicated by the dotted line 44, all the first and second auxiliary wirings 15 are provided so as to surround the display region 10d so as to be connected to the conductive ring 42 via the diode ring 44. Note that the conductive ring 42 and the plurality of diode rings 44 connected thereto may also be referred to together as a diode ring. As shown in FIG. 2(c), instead of the diodes 44a and 44b, the diode ring 44T may be formed by combining two diode-connected TFTs 44Ta and 44Tb.

In the same manner as the liquid crystal display panel 100, the liquid crystal display panel 200 also has first and second auxiliary wirings 15. In the liquid crystal display panel 200, the first and second auxiliary wirings 15 are used to carry out repairs as follows. Here also, a case where the disconnection 14f occurs in the source bus line 14a of the second display region 10db positioned on the lower side of the liquid crystal display panel 200 will be given as an example.

In the second display region 10db, the source bus line 14a in which the disconnection 14f has occurred is connected to the wiring (for example, a wiring formed from the same metal layer as the auxiliary capacitance wiring) 16 extending in the first direction at the connection point 14m1 at a position closer to the source driver 35 than the disconnection 14f. The wiring 16 and the second auxiliary wiring 15 are connected at the connection point 15m1. The second auxiliary wiring 15 is connected to the other wiring 16 extending in the first direction at the connection point 15m2, and the other wiring 16 is connected to the source bus line 14a in which the disconnection 14f has occurred at the connection point 15m2 (farther from the source driver 35) farther ahead of the disconnection 14f of the source bus line 14a in which the disconnection 14f has occurred. In this manner, the source signal voltage supplied from the source driver 35 to the source bus line 14a in which the disconnection 14f has occurred is also supplied ahead of the disconnection 14f of the source bus line 14a via the second auxiliary wiring 15 and the two wirings 16. In this manner, a predetermined source signal voltage is supplied to the entire source bus line 14a.

Next, with reference to FIG. 3, description will be given of the structure of the liquid crystal display panel according to Embodiment 3 and a method for correcting the same. FIG. 3 is a plan view schematically showing a structure of the TFT substrate 10A used in a liquid crystal display panel according to Embodiment 3. The liquid crystal display panel according to Embodiment 3 is obtained by using the TFT substrate 10A shown in FIG. 3 instead of the TFT substrate 10 of the liquid crystal display panel 100 shown in FIG. 1.

The TFT substrate 10A has a multi-pixel structure, and each pixel P has two subpixels SPa and SPb. The two subpixels SPa and SPb are arranged along the second direction (column direction). Both the first pixels belonging to the first display region of the liquid crystal display panel and the second pixels belonging to the second display region have the same structure.

It is possible for the two subpixels SPa and SPb to exhibit a different luminance from each other. In accordance with the source signal voltage (grayscale signal voltage) input to the pixel P, one subpixel SPa exhibits high luminance with respect to the luminance to be displayed by the pixel P, and the other subpixel SPb exhibits low luminance and luminance is exhibited corresponding to the source signal voltage input to the pixel P as a whole. The multi-pixel structure is particularly suitably used for a vertical alignment mode liquid crystal display panel, and makes it possible to improve the viewing angle characteristic of the gamma characteristics thereof. The structure of a liquid crystal display panel having a multi-pixel structure and a method for driving the same are described, for example, in Japanese Unexamined Patent Application Publication No. 2005-189804 (Japanese Patent No. 4265788) by the present applicant. For reference, the disclosure content of Japanese Unexamined Patent Application Publication No. 2005-189804 is incorporated in this specification in its entirety.

The TFT substrate 10A has two subpixel electrodes (a first subpixel electrode 11a and a second subpixel electrode 11b) corresponding to two subpixels (a first subpixel SPa and a second subpixel SPb). The two subpixel electrodes 11a and 11b forming one pixel P may be collectively referred to as a pixel electrode. The two subpixel electrodes 11a and 11b are, for example, supplied with source signal voltages from the common source bus line 14a or 14b via two TFTs 18a and 18b connected to a common gate bus line 12. Naturally, since it is sufficient to control the two TFTs 18a and 18b are ON/OFF at the same timing, connection to the common gate bus line 12 is not always necessary. The same also applies to the source bus line 14a or 14b. However, when the number of the gate bus lines and/or the number of the source bus lines increases, this is a factor causing the aperture ratio to decrease, thus the two TFTs corresponding to each of the two subpixels SPa and SPb forming one pixel P are preferably connected to a common gate bus line 12 and a common source bus line 14a or 14b.

The first subpixel SPa has a first auxiliary capacitance and the second subpixel SPb has a second auxiliary capacitance and, by supplying auxiliary capacitance voltages different to each other, from an auxiliary capacitance wiring CSa connected to the first auxiliary capacitance of the first subpixel SPa, and an auxiliary capacitance wiring CSb connected to the second auxiliary capacitance of the second subpixel SPb, the effective voltages applied to the liquid crystal layer of the first subpixel SPa and the liquid crystal layer of the second subpixel SPb are different from each other. Here, the auxiliary capacitance wirings CSa and CSb are electrically independent from the gate bus line 12. Here, in the entire liquid crystal display panel 100, for example, twelve kinds of auxiliary capacitance wirings, which are electrically independent from each other, such as the auxiliary capacitance wirings CSa and CSb are provided, and a voltage is supplied to the auxiliary capacitance electrode of the corresponding subpixel according to the phase of the auxiliary capacitance voltage. For example, twelve kinds of auxiliary capacitance voltages are supplied from twelve auxiliary capacitance main lines to each of the auxiliary capacitance wirings.

In a typical liquid crystal display panel, since the same voltage as the liquid crystal capacitance is applied to the auxiliary capacitance, the same voltage as the pixel electrode is supplied to one of the pair of electrodes forming the auxiliary capacitance, and the same voltage (common voltage) as the common electrode (counter electrode) is supplied to the other electrode. On the other hand, in a liquid crystal display panel having a multi-pixel structure, oscillation voltages (voltages oscillating within one vertical scanning period) which are different to each other are supplied from the auxiliary capacitance wirings CSa and CSb described above. Typically, the oscillating voltage is a voltage in which the phase is 1800 different between the auxiliary capacitance wiring CSa and the auxiliary capacitance wiring CSb. In the pair of electrodes of the auxiliary capacitance, the electrode connected to the auxiliary capacitance wiring may also be referred to as an auxiliary capacitance counter electrode.

The auxiliary capacitance wiring and the auxiliary capacitance electrode connected thereto are formed, for example, from the same metal layer (referred to as a gate metal layer) as the gate bus line. The dielectric layer of the auxiliary capacitance is formed of, for example, a gate insulating layer. The electrode formed on the dielectric layer on the auxiliary capacitance electrode is formed from the same conductive layer as the pixel electrode (subpixel electrode) or the same metal layer (source metal layer) as the source bus line, and is electrically connected to the drain of the TFT or the pixel electrode (subpixel electrode). Since the structure of these auxiliary capacitances is well known, illustration is omitted.

Each of the auxiliary capacitance wirings CSa and CSb of the TFT substrate 10A has a first auxiliary capacitance wiring 16_1 extending in the first direction and connected to the first auxiliary capacitance (auxiliary capacitance of the first subpixel SPa) belonging to one pixel row formed of a plurality of pixels arranged in the first direction, and a second auxiliary capacitance wiring 16_2 extending in the first direction and connected to a second auxiliary capacitance (the auxiliary capacitance of the second subpixel SPb) belonging to one pixel row formed of a plurality of pixels arranged in the first direction, and a third auxiliary capacitance wiring 16_3 provided in parallel with the first auxiliary capacitance wiring 16_1 and the second auxiliary capacitance wiring 16_2 associated with adjacent pixel rows and electrically connected to the first auxiliary capacitance wiring 16_1 and the second auxiliary capacitance wiring 16_2.

For example, each of the auxiliary capacitance wirings CSa and CSb further has the second auxiliary capacitance wiring 16_2 in which two pixels arranged in the second direction are set as the k-th row pixel and the k+1-th row pixel, and, in each pixel, the second subpixel SPb is arranged in the second direction of the first subpixel SPa, the second auxiliary capacitance wiring 16_2 being associated with the second subpixel SPb of the k-th row pixel, the first auxiliary capacitance wiring 16_1 associated with the first subpixel SPa of the k+l-th row pixel, a third auxiliary capacitance wiring 16_3 provided between the second auxiliary capacitance wiring 16_2 and the first auxiliary capacitance wiring 16_1, and an auxiliary capacitance coupling wiring 16cn electrically connecting the above. The auxiliary capacitance coupling wiring 16cn is electrically connected to the auxiliary capacitance electrodes of the first auxiliary capacitance (auxiliary capacitance of the first subpixel SPa) and the second auxiliary capacitance (auxiliary capacitance of the second subpixel SPb).

In this manner, providing the auxiliary capacitance wirings CSa and CSb with a branched structure (including a ladder structure) formed of a plurality of wirings makes it possible to reduce the resistance of the auxiliary capacitance wirings CSa and CSb. Accordingly, even in a high-definition and/or large-sized liquid crystal display panel, it is possible to suppress delays in the auxiliary capacitance voltage and the generation of waveform rounding. In addition, as described below, by cutting a part of the auxiliary capacitance wirings CSa and CSb having a branched structure to set these as electrically separate wirings, use is possible as a wiring extending in the first direction to connect the first auxiliary wiring 15 or the second auxiliary wiring 15.

With reference to FIG. 3, a description will be given of a method for correcting a case where the disconnection 14f occurs in the source bus line 14a. Arrows A0, A1, A2, and A3 in FIG. 3 indicate the flow of the source signal voltage supplied to the source bus line 14a in which the disconnection 14f has occurred.

When the disconnection 14f occurs, the source signal voltage is not supplied to the source bus line 14a positioned ahead of the disconnection 14f (the upper side in FIG. 3) in the path indicated by an arrow A0. The source signal voltage current-amplified by the second buffer circuit 34 is supplied to the second auxiliary wiring 15 in the path indicated by an arrow A1. This is as described with reference to FIG. 1.

The second auxiliary wiring 15 and a portion of the third auxiliary capacitance wiring 16_3 are connected to each other at a connection point 15m. Since wiring is not necessary ahead of the connection point 15m (the upper side in FIG. 3) of the second auxiliary wiring 15, the wiring is cut (the cutting point 15c). A portion of the third auxiliary capacitance wiring 16_3 and the source bus line 14a in which the disconnection 14f has occurred are connected to each other at a connection point 14m. At this time, the portion described above of the third auxiliary capacitance wiring 16_3 is cut at six points (cutting points 16c) in order to be electrically independent from the third auxiliary capacitance wiring 16_3. Two of these cutting points 16c are for partially separating the third auxiliary capacitance wiring 16_3, and the other four cutting points 16c are for separating the third auxiliary capacitance wiring 16_3 and two auxiliary capacitance coupling wirings 16cn connecting the first auxiliary capacitance wiring 16_1 and the second auxiliary capacitance wiring 16_2 to each other (two cutting point locations for one auxiliary capacitance coupling wiring). Since the third auxiliary capacitance wiring 16_3 is connected to the first auxiliary capacitance wiring 16_1 and the second auxiliary capacitance wiring 16_2 by another auxiliary capacitance coupling wiring 16cn, the increase in the resistance value of the auxiliary capacitance wiring CSa is slight, and there is no influence on the display quality.

In this manner, the output signal voltage from the second buffer circuit 34 passes through the second auxiliary wiring 15 as indicated by the arrow A1, passes through a part of the third auxiliary capacitance wiring 16_3 as indicated by an arrow A2, and is connected to the source bus line 14a ahead of the position at which the disconnection 14f has occurred. Here, although the connection point 14m is formed just ahead of the position at which the disconnection 14f has occurred, the connection point 14m is not limited thereto. The source signal voltage (current-amplified by the buffer circuit 34) supplied from the connection point 14m to the source bus line 14a passes through the source bus line 14a not only in the upward direction indicated by an arrow A3 but also in the opposite downward direction.

As described above, the cutting points 16c and 15c and the connection points 14m and 15m are formed using, for example, a known laser repair device. When the pixel electrode (the subpixel electrode 11a or the subpixel electrode 11b) is interposed at the time of irradiating the positions for forming the cutting points 16c and 15c and the connection points 14m and 15m with laser light, a part of the transparent conductive layer (for example, the ITO layer) forming the pixel electrode is scattered by being irradiated with the laser light, which may cause a defect. To suppress or inhibit this, for example, a notch is provided in the pixel electrode at the position irradiated with the laser light. In the example shown in FIG. 3, the subpixel electrode 11a has three notched portions 11ac1, 11ac2, and 11ac3, and the subpixel electrode 11b has three notched portions 11bc1, 11bc2, and 11bc3. Here, all the subpixel electrodes 11a and 11b have three notched portions at the same corresponding position. Three notched portions are provided on a side in the vicinity of the third auxiliary capacitance wiring 16_3. In addition, the notched portions 11ac1 and 11bc1 are provided on the side in the vicinity of the source bus line 14a corresponding to the subpixel electrodes 11a and 11b, and the notched portions 11ac2 and 11bc2 are provided on a side in the vicinity of the source bus line 14b corresponding to the subpixel electrodes 11a and 11b. That is, the notched portions 11ac1 and 11bc1 are provided at corners of the subpixel electrodes 11a and 11b in the vicinity of the intersection of the third auxiliary capacitance wiring 16_3 and the source bus line 14a, and the notched portions 11ac2 and 11bc2 are provided at corners of the subpixel electrodes 11a and 11b in the vicinity of intersections of the third auxiliary capacitance wiring 16_3 and the source bus line 14b. The notched portions 11ac3 and 11bc3 are provided in the vicinity of the intersection between the third auxiliary capacitance wiring 16_3 and the auxiliary capacitance coupling wiring 16cn.

Providing the notched portions 11ac1, 11ac2, 11ac3, 11bc1, 11bc2, and 11bc3 makes it possible to carry out the repairs where the length of a part of the second auxiliary wiring 15 and the third auxiliary capacitance wiring 16_3 is the shortest depending on the position at which the disconnection 14f has occurred.

Although the second auxiliary wiring 15 may be provided corresponding to all the pixel columns, this is a factor lowering the aperture ratio, thus, for example, as shown here, the second auxiliary wiring 15 may be provided at a ratio of one for three pixels. Three pixels (distinguished by the kind of hatching attached to the subpixel electrodes) arranged in the first direction (row direction) correspond to, for example, pixels of three primary colors of red, green, and blue. In a case where one color display pixel is formed of three primary color pixels as described above, one second auxiliary wiring 15 is provided for each color display pixel. In a case where one color display pixel is formed of four or more pixels, the second auxiliary wiring 15 may be provided in a ratio of one to four or more pixels. It is also possible to further decrease the number (density) of the second auxiliary wirings 15 and the number (density) of the notched portions, as will be described below.

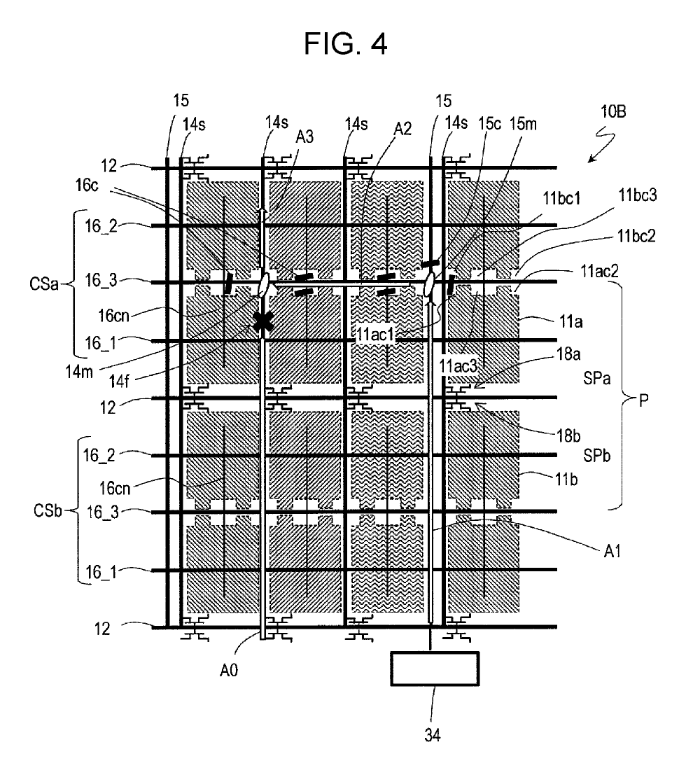

Above, a liquid crystal display panel having a double source structure was exemplified and the liquid crystal display panel according to the embodiment of the present invention and a method for correcting the same were described; however, it is also possible to apply the liquid crystal display panel according to the embodiment of the present invention to a liquid crystal display panel having a single source structure as shown in FIG. 4.

FIG. 4 is a plan view schematically showing a structure of the TFT substrate 10B used in a liquid crystal display panel according to Embodiment 4 of the present invention. A liquid crystal display panel according to Embodiment 4 is obtained by using the TFT substrate 10B shown in FIG. 4 instead of the TFT substrate 10 of the liquid crystal display panel 100 shown in FIG. 1.

The TFT substrate 10B has a single source structure. The TFT substrate 10A shown in FIG. 3 has two source bus lines 14a and 14b for each pixel column, while the TFT substrate 10B shown in FIG. 4 has only one source bus line 14s for each pixel column. As is apparent from a comparison between FIG. 4 and FIG. 3, the other configuration of the TFT substrate 10B is substantially the same as that of the TFT substrate 10A, and it is possible to correct the disconnection 14f in the same manner.

Next, with reference to FIG. 5, a description will be given of a liquid crystal display panel according to Embodiment 5 of the present invention and a method for correcting the same. FIG. 5 is a plan view schematically showing a structure of the TFT substrate 10C used in a liquid crystal display panel according to Embodiment 5. The liquid crystal display panel according to Embodiment 5 is obtained by using the TFT substrate 10C shown in FIG. 5 instead of the TFT substrate 10 of the liquid crystal display panel 100 shown in FIG. 1.

The TFT substrate 10C shown in FIG. 5 does not have the third auxiliary capacitance wiring 16_3 in the TFT substrate 10A shown in FIG. 3.

In the same manner as the TFT substrate 10A, the auxiliary capacitance wirings CSa and CSb of the TFT substrate 10C have the first auxiliary capacitance wiring 16_1 and the second auxiliary capacitance wiring 16_2, respectively, but do not have the third auxiliary capacitance wiring 16_3. The TFT substrate 10C has a second connection wiring 17 at a position corresponding to the third auxiliary capacitance wiring 16_3 in the TFT substrate 10A. The second connection wiring 17 is electrically independent from the auxiliary capacitance wirings CSa and CSb, and the auxiliary capacitance wirings CSa and CSb do not have the auxiliary capacitance coupling wiring 16cn in the TFT substrate 10A. The first auxiliary capacitance wiring 16_1 and the second auxiliary capacitance wiring 16_2 have an auxiliary capacitance electrode line 16s electrically connected to the respective auxiliary capacitance electrode. In the same manner as the previous diagram, FIG. 5 also shows the second display region of the TFT substrate 10C and the first connection wiring 17 corresponding to the second connection wiring 17 is formed in the first display region of the TFT substrate 10C.

The liquid crystal display panel of Embodiment 5 is able to be corrected in substantially the same manner as the liquid crystal display panel of Embodiment 3 by using the second connection wiring 17 instead of the third auxiliary capacitance wiring 16_3 of the liquid crystal display panel of Embodiment 3. However, since the second connection wiring 17 is electrically independent from the first auxiliary capacitance wiring 16_1 and the second auxiliary capacitance wiring 16_2 and does not have the auxiliary capacitance coupling wiring 16cn as in the TFT substrate 10A of the liquid crystal display panel of Embodiment 3, it is not necessary to cut off the auxiliary capacitance coupling wiring 16cn. Accordingly, as is apparent from a comparison between FIG. 3 and FIG. 5, the TFT substrate 10C has no cutting points 16c (four points) for cutting the auxiliary capacitance coupling wiring 16cn. In addition, the first subpixel electrode 11a and the second subpixel electrode 11b of the TFT substrate 10C do not have the notched portions 11ac3 and 11bc3 provided in the first subpixel electrode 11a and the second subpixel electrode 11b of the TFT substrate 10A. Accordingly, the liquid crystal display panel of Embodiment 5 has an advantage in that it is possible to make the aperture ratio larger than that of the liquid crystal display panel of Embodiment 3. Also in the TFT substrate 10C, all the pixel electrodes (the first subpixel electrode 11a and the second subpixel electrode 11b) have the notched portions 11ac1, 11ac2 or notched portions 11bc1, 11bc2. A description will be given below of an example of a liquid crystal display panel in which the number (density) of notched portions is further reduced.

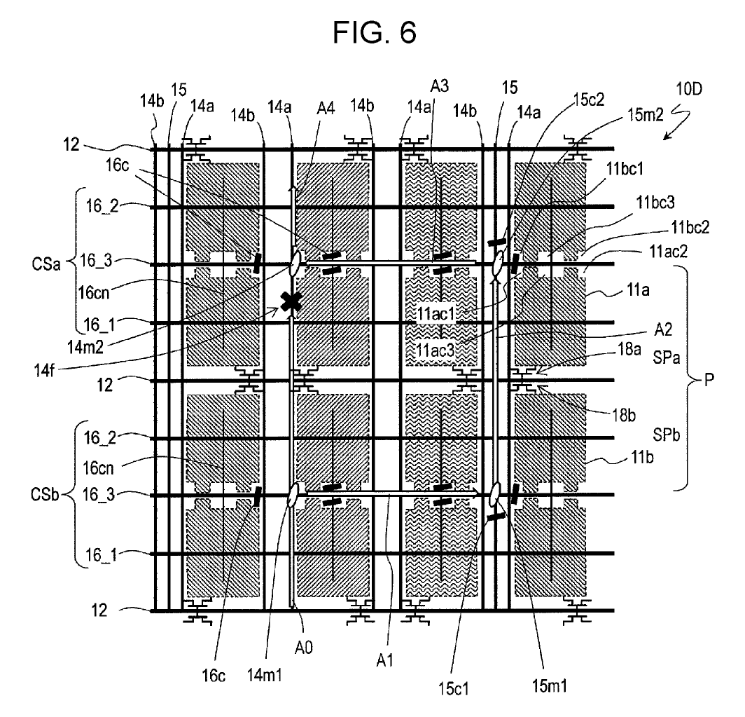

Next, referring to FIG. 6, a description will be given of the structure of the liquid crystal display panel according to Embodiment 6 and a method for correcting the same. FIG. 6 is a plan view schematically showing a structure of a TFT substrate 10D used in a liquid crystal display panel according to Embodiment 6. The liquid crystal display panel according to Embodiment 6 is obtained using the TFT substrate 10D shown in FIG. 6 instead of the TFT substrate 10 of the liquid crystal display panel 200 shown in FIG. 2.

The structure of the display region of the TFT substrate 10D is substantially the same as the structure of the TFT substrate 10A shown in FIG. 3. In the TFT substrate 10A, a desired signal voltage (a signal voltage obtained by current-amplifying a source signal) is supplied from the buffer circuit 34 to the second auxiliary wiring 15 when correcting the disconnection 14f, while in the TFT substrate 10D, the source signal voltage supplied to the source bus line 14a in which the disconnection 14f has occurred is supplied to the second auxiliary wiring 15 using a part of the third auxiliary capacitance wiring 16_3.

The connection point 14m1 is formed at a position which intersects with the third auxiliary capacitance wiring 16_3 behind (closer to the source driver 35) the position of the disconnection 14f of the source bus line 14a in which the disconnection 14f has occurred. The connection point 15m1 is formed at a position at which the third auxiliary capacitance wiring 16_3 and the second auxiliary wiring 15 intersect. In order to make a part of the third auxiliary capacitance wiring 16_3 connected to the second auxiliary wiring 15 electrically independent from the auxiliary capacitance wiring CSb, cutting is performed at six points (cutting points 16c). Since the portion (lower side in FIG. 6) behind the connection point 15m1 of the second auxiliary wiring 15 is not necessary, this portion is cut (cutting point 15cl).

The second auxiliary wiring 15 and a part of the third auxiliary capacitance wiring 16_3 intersecting with the source bus line 14a ahead of the portion of the source bus line 14a in which the disconnection 14f has occurred are connected to each other at the connection point 15m2. Since a part ahead of connection point 15m2 of the second auxiliary wiring 15 is not necessary (the upper side in FIG. 6), this part is cut (the cutting point 15c2). The part described above of the third auxiliary capacitance wiring 16_3 and the source bus line 14a in which the disconnection 14f has occurred are connected to each other at the connection point 14m2. At this time, in order to make the portion described above of third auxiliary capacitance wiring 16_3 electrically independent from the third auxiliary capacitance wiring 16_3, cutting is carried out at six points (cutting points 16c).

In this manner, the source signal voltage supplied to the source bus line 14a in which the disconnection 14f has occurred passes through the source bus line 14a as indicated by the arrow A0, passes through a part of the third auxiliary capacitance wiring 16_3 as indicated by the arrow A1, passes through the second auxiliary wiring 15 as indicated by the arrow A2, passes through a part of the third auxiliary capacitance wiring 16_3 as indicated by the arrow A3, and is connected to the source bus line 14a ahead of the position at which the disconnection 14f has occurred. Here, although the connection point 14m2 is formed just ahead of the position at which the disconnection 14f has occurred, the connection point 14m2 is not limited thereto. The source signal voltage supplied from the connection point 14m2 to the source bus line 14a is supplied through the source bus line 14a not only in the upward direction indicated by an arrow A4 but also in the opposite downward direction.

In this manner, when the disconnection correction is performed by using the third auxiliary capacitance wiring 16_3 and the second auxiliary wiring 15, the path through which the source signal voltage passes is lengthened, but only to a slight extent (for example, to the extent that the vertical direction length of the pixel+the horizontal direction length of the pixel×2), and there is almost no delay in the source signal voltage or change in the waveform due to this.

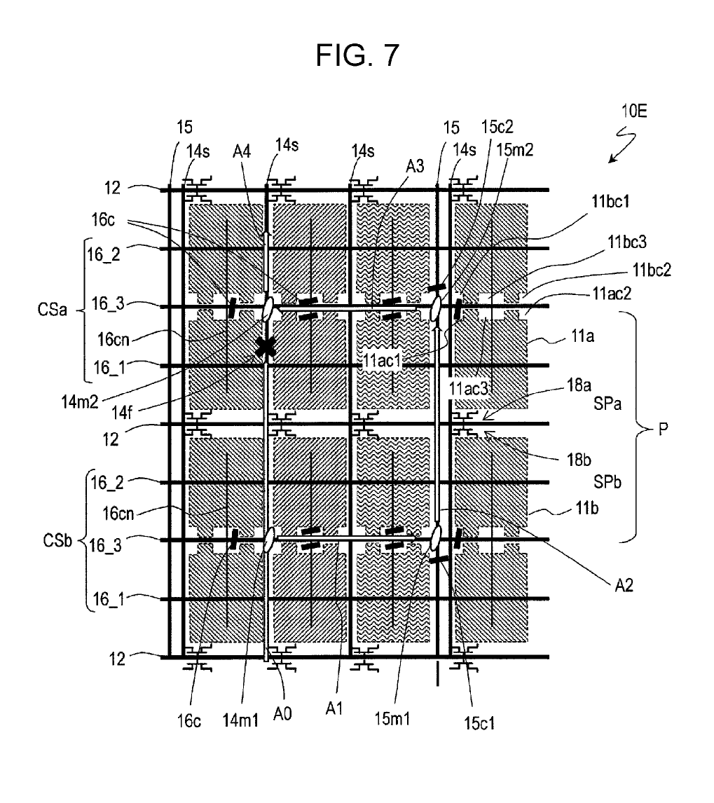

FIG. 7 is a plan view schematically showing a structure of a TFT substrate 10E used in a liquid crystal display panel according to Embodiment 7 of the present invention. The liquid crystal display panel according to Embodiment 7 is obtained by using the TFT substrate 10E shown in FIG. 7 instead of the TFT substrate 10 of the liquid crystal display panel 200 shown in FIG. 2.

The TFT substrate 10E has a single source structure. The TFT substrate 10D shown in FIG. 6 has two source bus lines 14a and 14b for each pixel column, while the TFT substrate 10E shown in FIG. 7 has only one source bus line 14s for each pixel column. As is apparent from a comparison between FIG. 7 and FIG. 6, in other respects, the configuration of the TFT substrate 10E is substantially the same as that of the TFT substrate 10D and it is possible to correct the disconnection 14f in the same manner.

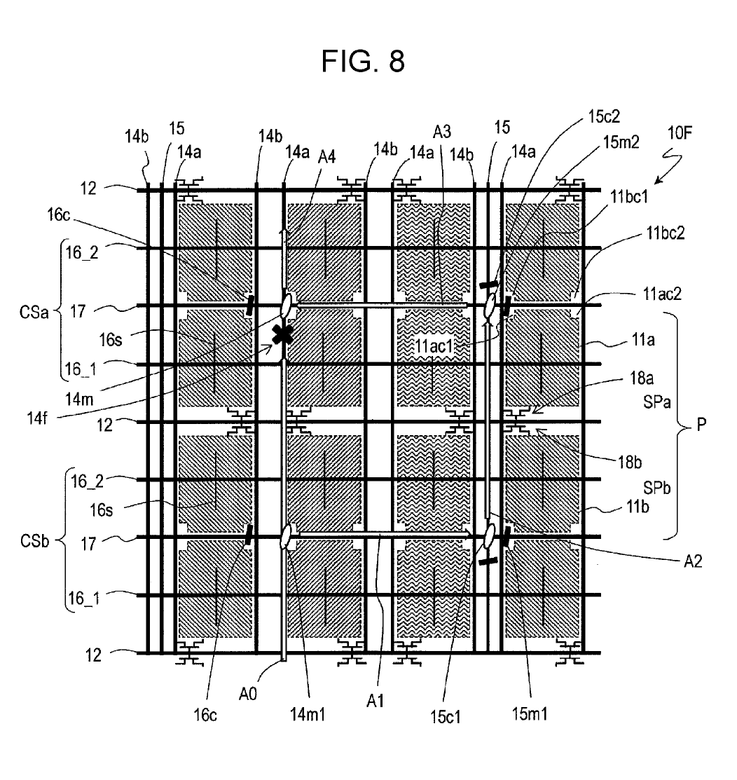

Next, with reference to FIG. 8, a description will be given of a liquid crystal display panel according to Embodiment 8 of the present invention and a method for correcting the same. FIG. 8 is a plan view schematically showing a structure of a TFT substrate 10F used in a liquid crystal display panel according to Embodiment 8. The liquid crystal display panel according to Embodiment 8 is obtained by using the TFT substrate 10F shown in FIG. 8 instead of the TFT substrate 10 of the liquid crystal display panel 200 shown in FIG. 2.

The TFT substrate 10F shown in FIG. 8 does not have the third auxiliary capacitance wiring 16_3 in the TFT substrate 10D shown in FIG. 6.

In the same manner as the TFT substrate 10D, the auxiliary capacitance wirings CSa and CSb of the TFT substrate 10F have the first auxiliary capacitance wiring 16_1 and the second auxiliary capacitance wiring 16_2, respectively, but do not have the third auxiliary capacitance wiring 16_3. The TFT substrate 10F has the second connection wiring 17 at a position corresponding to the third auxiliary capacitance wiring 16_3 in the TFT substrate 10D. The second connection wiring 17 is electrically independent from the auxiliary capacitance wirings CSa and CSb, and the auxiliary capacitance wirings CSa and CSb do not have the auxiliary capacitance coupling wiring 16cn in the TFT substrate 10D. The first auxiliary capacitance wiring 16_1 and the second auxiliary capacitance wiring 16_2 have an auxiliary capacitance electrode line 16s electrically connected to the respective auxiliary capacitance electrode. In the same manner as the previous diagram, FIG. 8 also shows a second display region of the TFT substrate 10F and, in the first display region of the TFT substrate 10F, a first connection wiring 17 corresponding to the second connection wiring 17 is formed.

The liquid crystal display panel of Embodiment 8 is able to be corrected in substantially the same manner as the liquid crystal display panel of Embodiment 6 by using the second connection wiring 17 instead of the third auxiliary capacitance wiring 16_3 of the liquid crystal display panel of Embodiment 6. However, the second connection wiring 17 is electrically independent from the first auxiliary capacitance wiring 16_1 and the second auxiliary capacitance wiring 16_2 and does not have the auxiliary capacitance coupling wiring 16cn as in the TFT substrate 10D of the liquid crystal display panel of Embodiment 6, thus it is not necessary to cut off the auxiliary capacitance coupling wiring 16cn. Accordingly, as is apparent from a comparison between FIG. 6 and FIG. 8, the TFT substrate 10F has no cutting points 16c (8 points) for cutting the auxiliary capacitance coupling wiring 16cn. In addition, the first subpixel electrode 11a and the second subpixel electrode 11b of the TFT substrate 10F do not have the notched portions 11ac3 and 11bc3 provided in the first subpixel electrode 11a and the second subpixel electrode 11b of the TFT substrate 10D. Accordingly, the liquid crystal display panel of Embodiment 8 has an advantage in that it is possible to make the aperture ratio larger than that of the liquid crystal display panel of Embodiment 6. Even in the TFT substrate 10F, all the pixel electrodes (the first subpixel electrode 11a and the second subpixel electrode 11b) have the notched portions 11ac1 and 11ac2 or the notched portions 11bc1 and 11bc2. A description will be given below of an example of a liquid crystal display panel in which the number (density) of notched portions is further reduced.

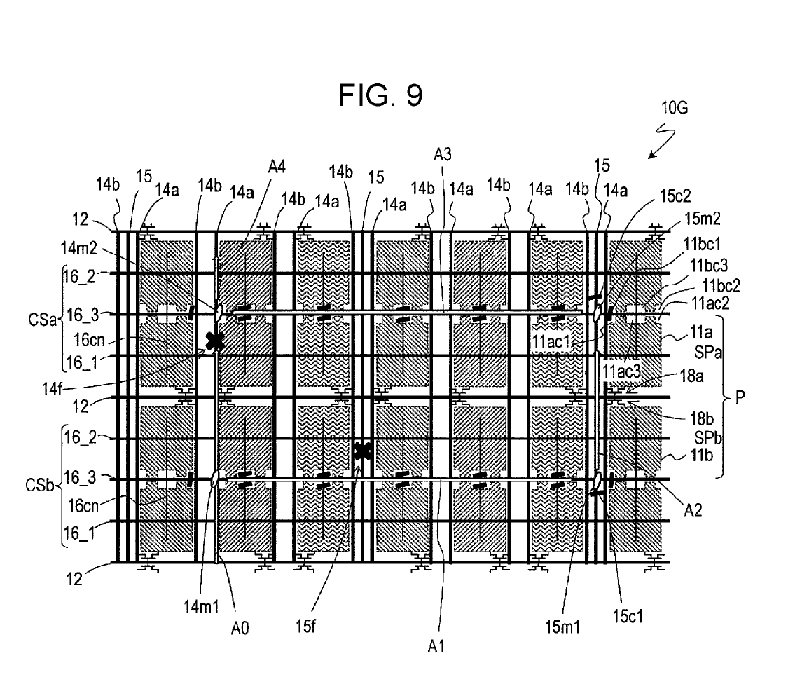

Next, with reference to FIG. 9, a description will be given of a liquid crystal display panel according to Embodiment 9 of the present invention and a method for correcting the same. FIG. 9 is a plan view schematically showing a structure of a TFT substrate 10G used in a liquid crystal display panel according to Embodiment 9. The liquid crystal display panel according to Embodiment 9 is obtained by using the TFT substrate 10G shown in FIG. 9 instead of the TFT substrate 10 of the liquid crystal display panel 200 shown in FIG. 2.

The TFT substrate 10G differs from the TFT substrate 10E shown in FIG. 7 in the point that a disconnection 15f has occurred in the second auxiliary wiring 15 and, accordingly, in the structure after correction.

In the TFT substrate 10E shown in FIG. 7, when the disconnection 15f occurs in the second auxiliary wiring 15 used for correcting the disconnection 14f of the source bus line 14a, correction is not possible as shown in FIG. 7. In that case, as in the TFT substrate 10G shown in FIG. 9, the second auxiliary wiring 15 which is next closest to the second auxiliary wiring 15 in which the disconnection 15f has occurred may be used. Naturally, the correction may be carried out by using the second auxiliary wiring 15 on the left side of the second auxiliary wiring 15 in which the disconnection 15f has occurred in FIG. 9.

When the disconnection 15f occurs in the second auxiliary wiring 15 nearest to the source bus line 14a in which the disconnection 14f has occurred as above, the transmission path of the source signal voltage associated with the disconnection correction becomes long, but since the length does not exceed several pixels, there is almost no delay in the source signal voltage or change in the waveform due to this.

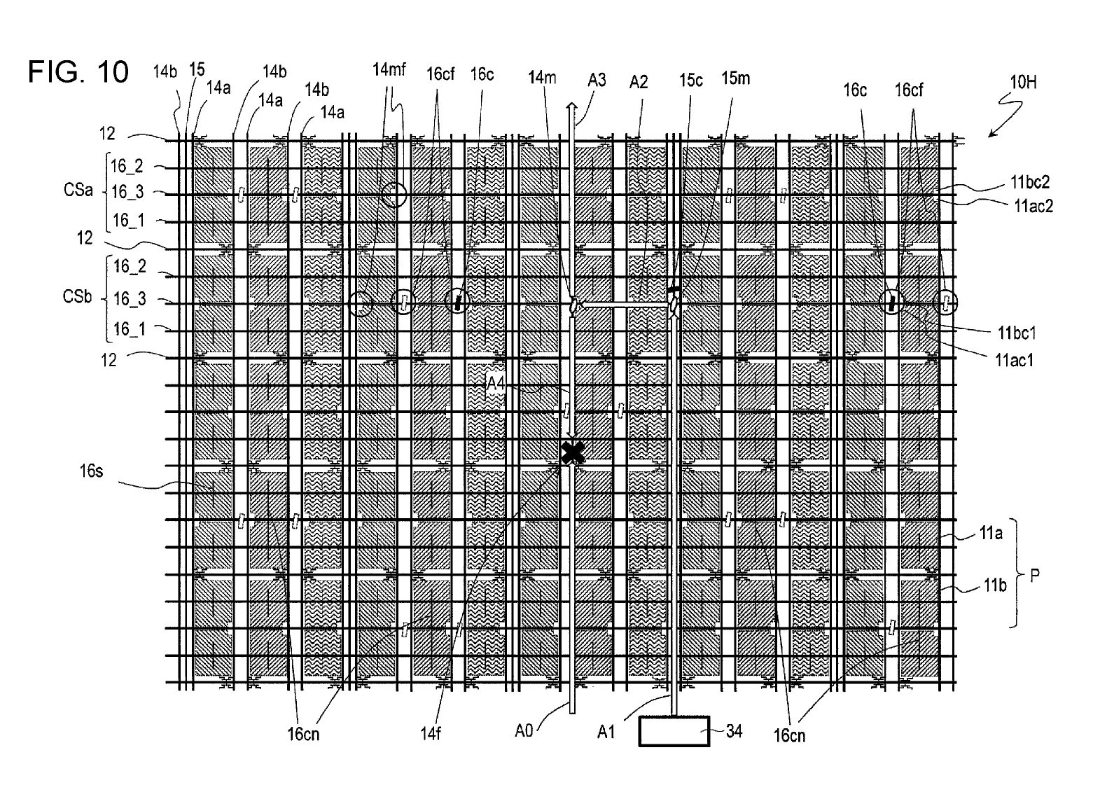

Next, with reference to FIG. 10, a description will be given of a liquid crystal display panel according to Embodiment 10 of the present invention and a method for correcting the same. FIG. 10 is a plan view schematically showing a structure of the TFT substrate 10H used in a liquid crystal display panel according to Embodiment 10. The liquid crystal display panel according to Embodiment 10 is obtained by using the TFT substrate 10H shown in FIG. 10 instead of the TFT substrate 10 of the liquid crystal display panel 100 shown in FIG. 1.

The basic method for correcting the TFT substrate 10H is the same as the method for correcting the TFT substrate 10A shown in FIG. 3. However, since the structure of the TFT substrate 10H is different from that of the TFT substrate 10A in the following point, it is possible to improve the aperture ratio and the correction ratio of the liquid crystal display panel due to this.

The subpixel electrodes 11a and 11b of the TFT substrate 10H have fewer notched portions than the subpixel electrodes 11a and 11b of the TFT substrate 10A. In the TFT substrate 10H, in the second direction, notched portions are alternately formed on the right side and the left side of the plurality of first subpixel electrodes 11a and the plurality of second subpixel electrodes 11b. Focusing on the pixel column at the right end in FIG. 10, the uppermost subpixel electrode 11b and the subpixel electrode 11a on the right end of the TFT substrate 10H have only the notched portions 11bc2 and 11ac2, and do not have the notched portions 11bc1 and 11ac1 and 11bc3 and 11ac3 of the subpixel electrodes 11b and 11a of the TFT substrate 10A.

In the TFT substrate 10A, the notched portions 11bc1 and 11ac1 are used for cutting the third auxiliary capacitance wiring 16_3 or for forming a connection point in the source bus line 14a and/or 14b in which a disconnection has occurred. In the TFT substrate 10H, the two subpixel electrodes 11b and the subpixel electrodes 11a immediately below the two subpixel electrodes described above in FIG. 10 have the notched portions 11bc1 and 11ac1. That is, in the TFT substrate 10H, the subpixel electrode 11a has only the notched portion 11ac1 or 11ac2, and the subpixel electrode 11b has only the notched portion 11bc1 or 11bc2. Looking at one pixel unit, a pixel in which the subpixel electrode 11a has a notched portion 11ac2, and the subpixel electrode 11b has a notched portion 11bc1, and a pixel in which the subpixel electrode 11a has a notched portion 11ac1, and the subpixel electrode 11b has the notched portion 11bc2 are alternately arranged in the column direction. Accordingly, for example, the notched portion 11bc2 of the subpixel electrode 11b belonging to the pixel of the k-th row and the notched portion 11ac2 of the subpixel electrode 11a belonging to the pixel of the k+l-th row are arranged so as to be adjacent via the third auxiliary capacitance wiring 16_3 (belonging to the auxiliary capacitance wiring CSa) with a gap therebetween (the uppermost row at the right end in FIG. 10). Next, the notched portion 11bc1 of the subpixel electrode 11b belonging to the pixel of the k+1-th row and the notched portion 11ac1 of the subpixel electrode 11a belonging to the pixel of the k+2-th row are arranged so as to be adjacent via the third auxiliary capacitance wiring 16_3 (belonging to the auxiliary capacitance wiring CSb) with a gap therebetween. Providing only the notched portions 11ac1, 11bc1, 11ac2, and 11bc2 in this manner makes it possible to reduce the total number (total area) of the notched portions and thus to improve the aperture ratio. That is, by limiting a portion 16cf for cutting the third auxiliary capacitance wiring 16_3 to a portion where the notched portions 11ac1 and 11bc1 are provided, a portion where the notched portions 11ac2 and 11bc2 are provided, and between the two source bus lines 14b and 14a which is not provided with the second auxiliary wiring 15, and limiting a portion 14mf in which the connection point 14m is formed in the source bus line 14a or 14b to a portion where the notched portions 11ac1 and 11bc1 are provided and a portion where the notched portions 11ac2 and 11bc2 are provided, it is possible to reduce the total number (total area) of the notched portions, thus, it is possible to improve the aperture ratio.

In addition, the subpixel electrodes 11a and 11b of the TFT substrate 10H do not have the notched portions 11ac3 and 11bc3 of the subpixel electrodes 11a and 11b of the TFT substrate 10A. In the TFT substrate 10A, the notched portions 11bc3 and 11ac3 are used when cutting the auxiliary capacitance coupling wiring 16cn. In the TFT substrate 10H, by selecting the position at which the auxiliary capacitance coupling wiring 16cn is provided, it is unnecessary to cut the auxiliary capacitance coupling wiring 16cn at the time of repair. For example, as shown in FIG. 10, the auxiliary capacitance coupling wiring 16cn is provided only for the auxiliary capacitance wiring overlapping the green pixel and the auxiliary capacitance coupling wiring 16cn is provided for every three green pixels arranged in the first direction. That is, the auxiliary capacitance coupling wiring 16cn is provided at a ratio of one for nine pixels arranged in the first direction. In the next row, the green pixel provided with the auxiliary capacitance coupling wiring 16cn is shifted by one in the first direction. In the TFT substrate 10H, the ratio of the pixels in which the auxiliary capacitance coupling wiring 16cn is formed in the entire display region is one to nine. Naturally, the above is only an example, and selecting the position at which the auxiliary capacitance coupling wiring 16cn is provided makes it possible to make it unnecessary to cut the auxiliary capacitance coupling wiring 16cn.

The repair efficiency of the liquid crystal display panel having the TFT substrate 10A of FIG. 3 and the liquid crystal display panel having the TFT substrate 10H of FIG. 10 will be compared. For example, the process time for forming the cutting point or the connection point is 1 minute, and the respective correction rates (correction success rate) are set to 98%.

For the correction of the liquid crystal display panel having the TFT substrate 10A in FIG. 3, it is necessary to form seven cutting points (six cutting points 16c and one cutting point 15c) and two connection points (one 14m and one 15m). Then, the total correction time is 9 minutes and the total correction rate is 83%. On the other hand, in the correction of the liquid crystal display panel having the TFT substrate 10H in FIG. 10, it is sufficient to form three cutting points (two cutting points 16c and one cutting point 15c) and two connection points (one 14m and one 15m). Then, the total correction time is 5 minutes and the total correction rate is 90%.

In this manner, as exemplified by the TFT substrate 10H in FIG. 10, reducing the number of notched portions and selecting the position at which the auxiliary capacitance coupling wiring 16cn is provided makes it possible to shorten the correction time and to improve the correction rate. It is also possible to apply such a structure to the TFT substrate 10B shown in FIG. 4. In addition, since the TFT substrate 10C shown in FIG. 5 has the second connection wiring 17 instead of the third auxiliary capacitance wiring 16_3 and does not have the auxiliary capacitance coupling wiring 16cn, although it is not possible to reduce the auxiliary capacitance coupling wiring 16cn, it is possible to obtain the effect of improving the aperture ratio and improving the correction rate by reducing the notched portions.

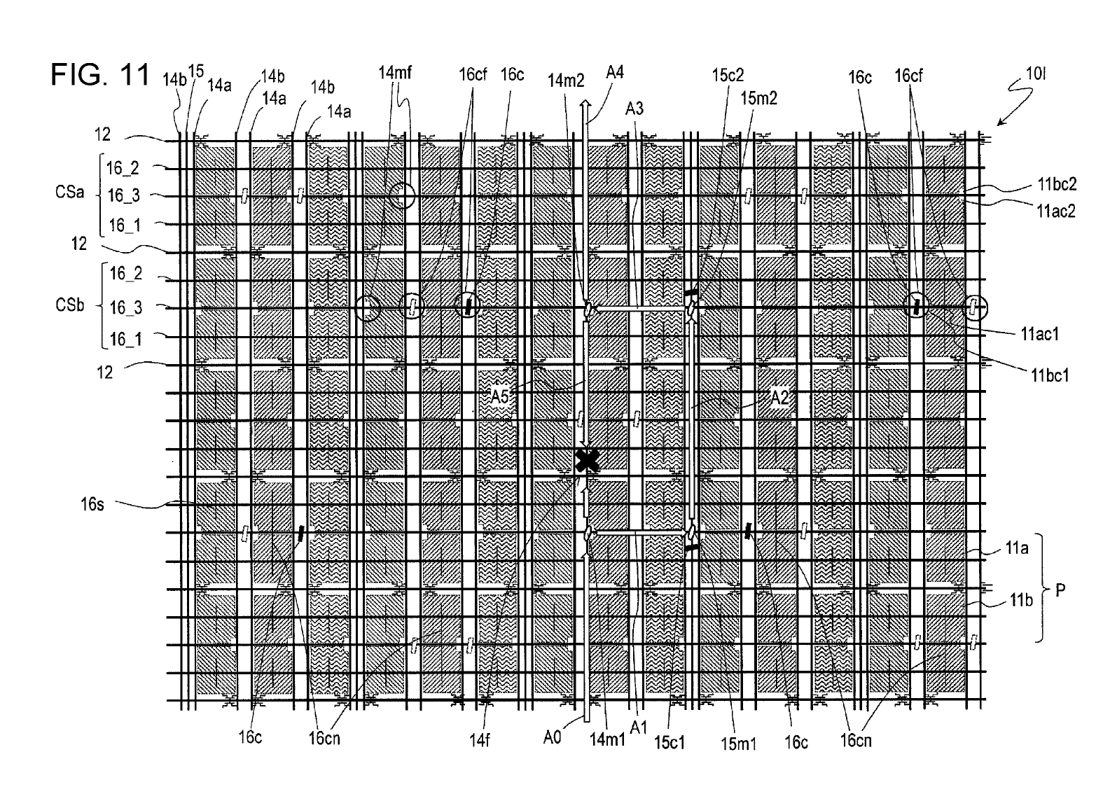

Next, with reference to FIG. 11, a description will be given of a liquid crystal display panel according to Embodiment 11 of the present invention and a method for correcting the same. FIG. 11 is a plan view schematically showing a structure of the TFT substrate 10I used in a liquid crystal display panel according to Embodiment 11. The liquid crystal display panel according to Embodiment 11 is obtained by using the TFT substrate 10I shown in FIG. 11 instead of the TFT substrate 10 of the liquid crystal display panel 200 shown in FIG. 2.

The basic method for correcting the TFT substrate 10I is the same as the method for correcting the TFT substrate 10D shown in FIG. 6. However, similarly to the TFT substrate 10H, since the TFT substrate 10I reduces the number of notched portions and selects the position at which the auxiliary capacitance coupling wiring 16cn is provided, it is possible to shorten the correction time and to improve the correction rate. Also in the TFT substrate 10I, the ratio of the pixels in which the auxiliary capacitance coupling wiring 16cn is formed in the entire display region is one to nine. Naturally, the above is only an example, and selecting the position at which the auxiliary capacitance coupling wiring 16cn is provided makes it possible to make it unnecessary to cut the auxiliary capacitance coupling wiring 16cn.

The repair efficiency of the liquid crystal display panel having the TFT substrate 10D of FIG. 6 and the liquid crystal display panel having the TFT substrate 10I of FIG. 11 will be compared. As before, the process time for forming the cutting point or connection point is 1 minute, and the respective correction rate (correction success rate) is 98%.

In the correction of the liquid crystal display panel having the TFT substrate 10D of FIG. 6, it is necessary to form 14 cutting points (12 cutting points 16c and 2 cutting points 15c1 and 15c2) and 4 connection points (connection points 14m1 and 14m2 and connection points 15m1 and 15m2). Then, the total correction time is 18 minutes and the total correction rate is 70%. On the other hand, in the correction of the liquid crystal display panel having the TFT substrate 10I of FIG. 11, it is sufficient to form only three cutting points (two cutting points 16c and one cutting point 15c) and two connection points (one 14m and one 15m). Then, the total correction time is 5 minutes and the total correction rate is 90%.

In this manner, as exemplified by the TFT substrate 10I of FIG. 11, reducing the number of notched portions and selecting the position at which the auxiliary capacitance coupling wiring 16cn is provided makes it possible to shorten the correction time and improve the correction rate. It is also possible to apply such a structure to the TFT substrate 10E shown in FIG. 7. In addition, since the TFT substrate 10F shown in FIG. 8 has the second connection wiring 17 instead of the third auxiliary capacitance wiring 16_3 and does not have the auxiliary capacitance coupling wiring 16cn, although it is not possible to reduce the auxiliary capacitance coupling wiring 16cn, it is possible to obtain the effect of improving the aperture ratio and improving the correction rate by reducing the notched portions.

If the number of notched portions is reduced as in the TFT substrates 10H and 10I, the path through which the source signal voltage passes becomes longer due to the disconnection correction, but the length is several % or less of the length of the source bus line, there is almost no delay in the source signal voltage or change in the waveform due to this.

In the liquid crystal display panel of the embodiment described above, the cutting portions of the third auxiliary capacitance wiring 16_3 or the first and second connection wirings 17 used for connecting the first and second auxiliary wirings 15 and the source bus line 14a or 14b in which the disconnection 14f has occurred are predetermined. In particular, when adopting a configuration in which the number of notched portions is reduced as in the TFT substrates 10H and 10I, the number of planned cutting portions is further reduced. It is preferable that the planned cutting portions have a structure which is able to be easily cut.

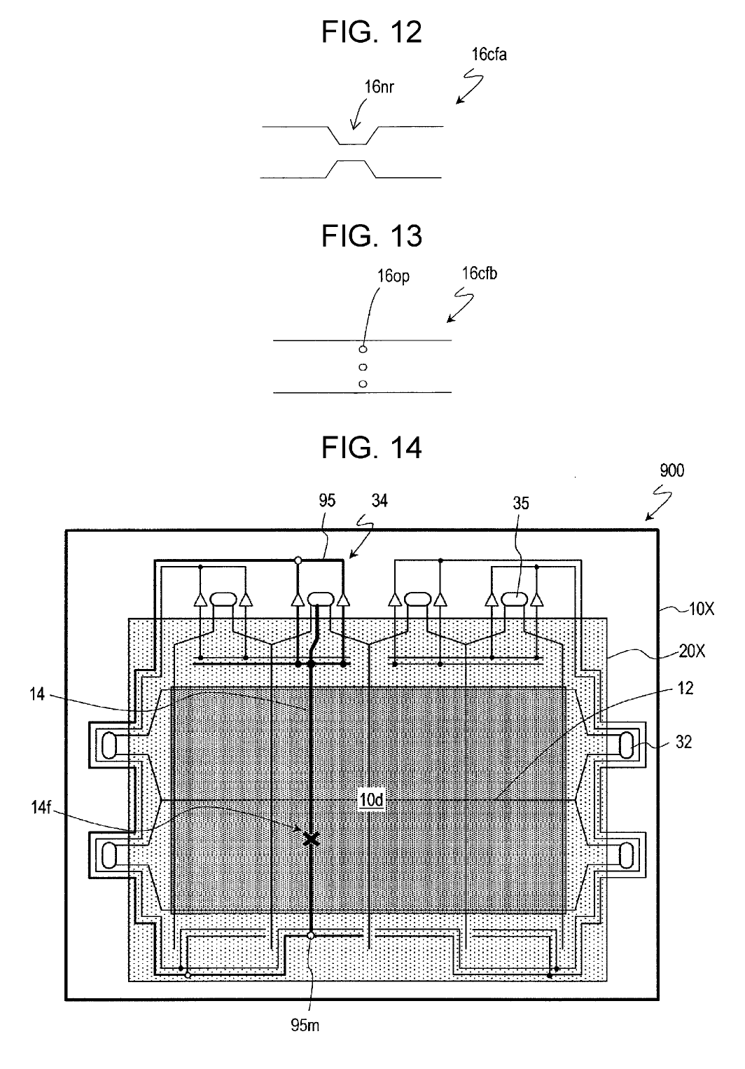

For example, a portion 16nr having a narrow line width may be formed as in the planned cutting portion 16cfa of the third auxiliary capacitance wiring 16_3 shown in FIG. 12. In addition, a plurality of openings 16op may be formed as in a planned cutting portion 16cfb of the third auxiliary capacitance wiring 16_3 shown in FIG. 13. In addition, it is possible to widely use a structure in which the metal material forming the third auxiliary capacitance wiring 16_3 is reduced at the planned cutting portion 16cf.

In the embodiment described above, a liquid crystal display panel having a multi-structure was exemplified, but it is also possible to apply the embodiment according to the present invention to a liquid crystal display panel not having a multi-pixel structure.

For example, the liquid crystal display panel may have a configuration which has a plurality of auxiliary capacitance wirings extending in the first direction in which each of a plurality of pixels has an auxiliary capacitance with each of the plurality of auxiliary capacitance wirings being connected to the auxiliary capacitances belonging to one pixel row formed of a plurality of first pixels or a plurality of second pixels arranged in a first direction in a plurality of first pixels or a plurality of second pixels, in which at least some of the plurality of auxiliary capacitance wirings have a branch structure. It is possible for a part of the branch structure of the auxiliary capacitance wirings to be used for correcting the disconnection by being partially cut as in the third auxiliary capacitance wiring in the liquid crystal display panel of the embodiment described above.

Naturally, a connection wiring may be provided instead of forming the auxiliary capacitance wiring as a branch structure. For example, the liquid crystal display panel may have a configuration which further has a plurality of first connection wirings extending in the first direction with each being associated with one pixel row formed of a plurality of first pixels arranged in a first direction in a plurality of first pixels, and plurality of second connection wirings extending in the first direction with each being associated with one pixel row formed of a plurality of second pixels arranged in a first direction in a plurality of second pixels.

The TFTs of the liquid crystal display panels 100 and 200 according to the embodiments of the present invention may be any known TFT such as an amorphous silicon TFT (a-Si TFT), a polysilicon TFT (p-Si TFT), and a microcrystalline silicon TFT (μC-Si TFT) and it is preferable to use a TFT (oxide TFT) having an oxide semiconductor layer.

The oxide semiconductor included in the oxide semiconductor layer may be an amorphous oxide semiconductor or a crystalline oxide semiconductor having a crystalline portion. Examples of the crystalline oxide semiconductor include a polycrystalline oxide semiconductor, a microcrystalline oxide semiconductor, and a crystalline oxide semiconductor in which the c-axis is oriented to be substantially perpendicularly to the layer surface.

The oxide semiconductor layer may have a laminated structure of two or more layers. In the case where the oxide semiconductor layer has a laminated-layer structure, the oxide semiconductor layer may include an amorphous oxide semiconductor layer and a crystalline oxide semiconductor layer. Alternatively, a plurality of crystalline oxide semiconductor layers having different crystal structures may be included. In addition, a plurality of amorphous oxide semiconductor layers may be included. In a case where the oxide semiconductor layer has a two-layer structure including a higher layer and a lower layer, the energy gap of the oxide semiconductor included in the higher layer is preferably larger than the energy gap of the oxide semiconductor included in the lower layer. However, in a case where the difference in energy gap between these layers is relatively small, the energy gap of the lower layer oxide semiconductor may be larger than the energy gap of the higher layer oxide semiconductor.

The material, structure, and film formation method of the amorphous oxide semiconductor and each of the above-described crystalline oxide semiconductors, the configuration of the oxide semiconductor layer having a laminated structure, and the like are described in, for example, Japanese Unexamined Patent Application Publication No. 2014-007399. For reference, all the disclosure content of Japanese Unexamined Patent Application Publication No. 2014-007399 is incorporated herein.

The oxide semiconductor layer may include, for example, at least one kind of metal element out of In, Ga, and Zn. The oxide semiconductor layer includes, for example, an In—Ga—Zn—O-based semiconductor (for example, indium gallium zinc oxide). Here, the In—Ga—Zn—O-based semiconductor is a ternary oxide of In (indium), Ga (gallium), and Zn (zinc), and the ratio (composition ratio) of In, Ga, and Zn is not particularly limited and includes, for example, In:Ga:Zn=2:2:1, In:Ga:Zn=1:1:1, In:Ga:Zn=1:1:2, and the like. It is possible to form such an oxide semiconductor layer from an oxide semiconductor film including an In—Ga—Zn—O-based semiconductor. Here, a channel etched-type TFT having an active layer including an oxide semiconductor, such as an In—Ga—Zn—O-based semiconductor, may be referred to as “CE-OS-TFT”.

The In—Ga—Zn—O-based semiconductor may be amorphous or crystalline. As a crystalline In—Ga—Zn—O-based semiconductor, a crystalline In—Ga—Zn—O-based semiconductor in which the c-axis is oriented to be substantially perpendicular to the layer surface is preferable.

Here, the crystal structure of a crystalline In—Ga—Zn—O-based semiconductor is disclosed in, for example, Japanese Unexamined Patent Application Publication No. 2014-007399, Japanese Unexamined Patent Application Publication No. 2012-134475, and Japanese Unexamined Patent Application Publication No. 2014-209727. For reference, all of the disclosures of Japanese Unexamined Patent Application Publication No. 2012-134475 and Japanese Unexamined Patent Application Publication No. 2014-209727 are incorporated herein. Since a TFT having an In—Ga—Zn—O-based semiconductor layer has high mobility (more than 20 times compared to a-Si TFT) and low leakage current (less than 1/100th compared to a-Si TFT), this TFT is suitably used as a driving TFT (for example, a TFT included in a drive circuit provided on the same substrate as a display region around a display region including a plurality of pixels) and a pixel TFT (TFT provided in a pixel).

Instead of the In—Ga—Zn—O-based semiconductor, the oxide semiconductor layer may include another oxide semiconductor. For example, an In—Sn—Zn—O-based semiconductor (for example, In₂O₃—SnO₂—ZnO; InSnZnO) may be included. The In—Sn—Zn—O-based semiconductor is a ternary oxide of In (indium), Sn (tin) and Zn (zinc). Alternatively, the oxide semiconductor layer may be an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, CdO (cadmium oxide), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, and the like.

### INDUSTRIAL APPLICABILITY

In particular, it is possible to widely use the liquid crystal display panel and the method for correcting the same of the present invention as a large liquid crystal display panel for high-definition television applications and a method for correcting disconnection of the source bus line.

### REFERENCE SIGNS LIST

10, 10A to 10I TFT SUBSTRATE
10d DISPLAY REGION
10da FIRST DISPLAY REGION (UPPER DISPLAY REGION)
10db SECOND DISPLAY REGION (LOWER DISPLAY REGION)
12 GATE BUS LINE
14a, 14b SOURCE BUS LINE
14f DISCONNECTION
14m, 14m1, 14m2 CONNECTION POINT
15 FIRST AND SECOND AUXILIARY WIRING
15m, 15m1, 15m2 CONNECTION POINT
16 WIRING EXTENDING IN FIRST DIRECTION (AUXILIARY CAPACITANCE WIRING)
32 GATE DRIVER
34 FIRST AND SECOND BUFFER CIRCUIT
34a, 34b BUFFER
35 FIRST AND SECOND SOURCE DRIVER
36a, 36b, 36c, 36d BUFFER CONNECTION WIRING
37 INPUT WIRING
38 OUTPUT WIRING
100, 200 LIQUID CRYSTAL DISPLAY PANEL

1. A liquid crystal display panel comprising:
a first display region having a plurality of first pixels arranged in a first direction and a second direction different from the first direction;
a second display region having a plurality of second pixels arranged in the first direction and the second direction and provided at a position different from the first display region;
a plurality of first transistors provided in the first display region and each connected to any one of the plurality of first pixels;
a plurality of second transistors provided in the second display region and each connected to any one of the plurality of second pixels;
a plurality of first gate bus lines each extending in the first direction and connected to any one of the plurality of first transistors;
a plurality of second gate bus lines each extending in the first direction and connected to any one of the plurality of second transistors;
a plurality of first source bus lines each extending in the second direction and connected to any one of the plurality of first transistors;
a plurality of second source bus lines each extending in the second direction and connected to any one of the plurality of second transistors;
a plurality of first auxiliary wirings each extending in the second direction and provided between two first pixels adjacent to each other in the first direction in the plurality of first pixels;
a plurality of second auxiliary wirings each extending in the second direction and provided between two second pixels adjacent to each other in the first direction in the plurality of second pixels;
a first source driver provided around the first display region and supplying a display signal voltage to the plurality of first source bus lines; and
a second source driver provided around the second display region and supplying a display signal voltage to the plurality of second source bus lines.

2. The liquid crystal display panel according to claim 1,
wherein the plurality of first auxiliary wirings and the plurality of second auxiliary wirings are arranged at a frequency with a ratio of one or less with respect to three first pixels and three second pixels arranged in the first direction, respectively.

3. The liquid crystal display panel according to claim 1, further comprising:
a first buffer circuit provided between the first source driver and the plurality of first auxiliary wirings; and
a second buffer circuit provided between the second source driver and the plurality of second auxiliary wirings.

4. The liquid crystal display panel according to claim 1, further comprising
a conductive ring provided to surround the first display region and the second display region,
wherein the plurality of first auxiliary wirings and the plurality of second auxiliary wirings are connected to the conductive ring.

5. The liquid crystal display panel according to claim 1, further comprising:
a plurality of first connection wirings extending in the first direction and each associated with one pixel row formed of a plurality of first pixels arranged in the first direction in the plurality of first pixels; and
a plurality of second connection wirings extending in the first direction and each associated with one pixel row formed of a plurality of second pixels arranged in the first direction in the plurality of second pixels.

6. The liquid crystal display panel according to claim 1,
wherein each of the plurality of first pixels and the plurality of second pixels has an auxiliary capacitance, the display panel further comprising:
a plurality of auxiliary capacitance wirings extending in the first direction and each connected to the auxiliary capacitances belonging to one pixel row formed of a plurality of first pixels or a plurality of second pixels arranged in the first direction in the plurality of first pixels or the plurality of second pixels, and
wherein at least part of the plurality of auxiliary capacitance wirings have a branched structure.

7. The liquid crystal display panel according to claim 1, further comprising
a plurality of pixel electrodes corresponding to each of the plurality of first pixels and the plurality of second pixels,
wherein at least part of the plurality of pixel electrodes have a notched portion on a side close to at least one associated source bus line in the plurality of first source bus lines and the plurality of second source bus lines.

8. The liquid crystal display panel according to claim 1,
wherein each of the plurality of first pixels and the plurality of second pixels has a first subpixel and a second subpixel arranged in the second direction, the first subpixel has a first auxiliary capacitance, and the second subpixel has a second auxiliary capacitance, the display panel further comprising:
a plurality of first auxiliary capacitance wirings extending in the first direction and each connected to the first auxiliary capacitances belonging to one pixel row formed of a plurality of first pixels or a plurality of second pixels arranged in the first direction in the plurality of first pixels or the plurality of second pixels,
a plurality of second auxiliary capacitance wirings extending in the first direction and each connected to the second auxiliary capacitances belonging to one pixel row formed of a plurality of first pixels or a plurality of second pixels arranged in the first direction in the plurality of first pixels or the plurality of second pixels; and
a plurality of third auxiliary capacitance wirings each provided in parallel with a first auxiliary capacitance wiring and a second auxiliary capacitance wiring associated with pixel rows adjacent to each other, and electrically connected to the first auxiliary capacitance wiring and the second auxiliary capacitance wiring.

9. The liquid crystal display panel according to claim 8,
wherein two pixels arranged in the second direction are set as a k-th row pixel and a k+1-th row pixel, and a second subpixel in each of the two pixels is arranged next to a first subpixel in the second direction, the liquid crystal display panel further comprising
an auxiliary capacitance coupling wiring electrically connecting a second auxiliary capacitance wiring associated with the second subpixel of the k-th row pixel, a first auxiliary capacitance wiring associated with the first subpixel of the k+1-th row pixel, and a corresponding third auxiliary capacitance wiring provided between the second auxiliary capacitance wiring and the first auxiliary capacitance wiring in the plurality of third auxiliary capacitance wirings.

10. The liquid crystal display panel according to claim 9,
wherein the auxiliary capacitance coupling wiring is formed only in preselected pixels, and a ratio of the pixels in which the auxiliary capacitance coupling wiring is formed is one ninth or less.

11. The liquid crystal display panel according to claim 1,
wherein each of the plurality of first pixels and the plurality of second pixels has a first subpixel and a second subpixel arranged in the second direction, the first subpixel has a first auxiliary capacitance, and the second subpixel has a second auxiliary capacitance, the display panel further comprising:
a plurality of first auxiliary capacitance wirings extending in the first direction and each connected to the first auxiliary capacitances belonging to one pixel row formed of a plurality of first pixels or a plurality of second pixels arranged in the first direction in the plurality of first pixels or the plurality of second pixels;
a plurality of second auxiliary capacitance wirings extending in the first direction and each connected to the second auxiliary capacitances belonging to one pixel row formed of a plurality of first pixels or a plurality of second pixels arranged in the first direction in the plurality of first pixels or the plurality of second pixels;
a plurality of first connection wirings extending in the first direction and each associated with one pixel row formed of a plurality of first pixels arranged in the first direction in the plurality of first pixels; and
a plurality of second connection wirings extending in the first direction and each associated with one pixel row formed of a plurality of second pixels arranged in the first direction in the plurality of second pixels.

12. The liquid crystal display panel according to claim 8, further comprising:
a plurality of first subpixel electrodes corresponding to each of the plurality of first subpixels; and
a plurality of second subpixel electrodes corresponding to each of the plurality of second subpixels,
wherein part of each of the plurality of first subpixel electrodes and the plurality of second subpixel electrodes have a notched portion on a side close to at least one associated source bus line in the plurality of first source bus lines and the plurality of second source bus lines.

13. The liquid crystal display panel according to claim 12,
wherein the notched portions are alternately formed in the second direction on a right side and a left side of the plurality of first subpixel electrodes and the plurality of second subpixel electrodes.

14. A correction method for the liquid crystal display panel according to claim 1, the method comprising any one of:
a step in which, when a disconnection occurs in one of the plurality of first source bus lines, the first source bus line where the disconnection has occurred and one of the plurality of first auxiliary wirings are connected; or
a step in which, when a disconnection occurs in one of the plurality of second source bus lines, the second source bus line where the disconnection has occurred and one of the plurality of second auxiliary wirings are connected.

15. The correction method according to claim 14,
wherein the liquid crystal display panel has a plurality of wirings provided in the first display region and the second display region, and each extending in the first direction and electrically independent from the plurality of the first gate bus lines and the plurality of second gate bus lines, the method further comprising:
a step of connecting via one of the plurality of wirings between the first source bus line where the disconnection has occurred and the one of the first auxiliary wirings or between the second source bus line where the disconnection has occurred and the one of the second auxiliary wirings.
